(19) United States
(12) Patent Application Publication
(10) Pub. No.: US 2023/0290916 A1
(43) Pub. Date: Sep. 14, 2023

(54) DISPLAY DEVICE USING MICRO LED

(71) Applicant: LG ELECTRONICS INC., Seoul (KR)

(72) Inventors: Jaegwang UM, Seoul (KR); Dohyung LEE, Seoul (KR); Sungguk LEE, Seoul (KR); Sangdae PARK, Seoul (KR); Hwankuk YUH, Seoul (KR); Sunju LEE, Seoul (KR)

(73) Assignee: LG ELECTRONICS INC., Seoul (KR)

(21) Appl. No.: 18/014,012

(22) PCT Filed: Jul. 3, 2020
(86) PCT No.: PCT/KR2020/008741

§ 371 Date: Dec. 30, 2022

(51) Int. Cl. H01L 33/62; H01L 25/075; H01L 25/16; H01L 27/12

(52) U.S. Cl. CPC H01L 33/62; H01L 25/0753; H01L 25/167; H01L 27/124

(57) ABSTRACT

The present invention is applicable to a display device-related technical field, and relates to, for example, a display device using a micro light-emitting diode (LED). The present invention provides the display device using an LED, wherein the display device may comprise: a thin film transistor (TFT) substrate including a TFT for driving an active matrix and a connection pad connected to the TFT; a light-emitting package including a unit pixel disposed on the TFT substrate and electrically connected to the connection pad, and including a transparent resin layer, a wiring layer positioned on the TFT substrate, and at least one LED positioned between the TFT substrate and the transparent resin layer, electrically connected to the wiring layer, and each forming a sub-pixel; and connection wiring electrically connecting the wiring layer and the connection pad to each other.

### TECHNICAL FIELD

The present disclosure is applicable to a display device-related technical field, and relates to, for example, a display device using a micro light emitting diode (LED).

### BACKGROUND

Recently, in a field of a display technology, display devices having excellent characteristics such as thinness, flexibility, and the like have been developed. On the other hand, currently commercialized major displays are represented by a LCD (liquid crystal display) and an OLED (organic light emitting diode).

On the other hand, LED (light emitting diode), which is a well-known semiconductor light-emitting element that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light-emitting element may be proposed. Such light emitting diode has various advantages, such as long lifespan, low power consumption, excellent initial driving characteristics, high vibration resistance, and the like, compared to a filament-based light-emitting element.

Conventional uses of the LED were mainly for lighting or backlighting, and in this case, because an action of emitting light is central, problems of a color sharpness and a diffused reflection action of the LED have not been highlighted.

However, as the LED gradually gets smaller and has entered a realm of mini or micro, displays that use the LED or a package using the LED as a light source (R/G/B) in units of a (sub) pixel are being used or being in development.

FIG. 1 is a schematic diagram showing an example of a conventional LED package-based display device.

Referring to FIG. 1, in a conventional LED package-based display device 10, switching thin film transistors (TFTs) 12 for driving in units of the pixels are arranged on a glass substrate 11 in units of the sub-pixels. An electrode 13 coated with an insulating layer 14 and an LED 15 connected to the electrode 13 are installed on each of the TFTs 12.

An insulating film, a phosphor, and other organic material layers form a composite layer 16 on each of the LEDs 15, and a planarizing layer 17 is disposed to flatten each of the composite layers.

In this regard, a thickness a of the substrate 11 is approximately 500 μm, a thickness b of the TFT 12 is approximately 2 μm, and a thickness c of the insulating layer 14 is approximately 5 μm. Further, when the LED 15 is the micro LED, a thickness d2 thereof is approximately 10 μm, and a thickness d1 of the composite layer 16 is approximately 200 μm. Thus, a sum of the thicknesses d of the LED 15 and the composite layer 16 is approximately in a range from 70 to 200 μm.

As such, when using the LED package as the light source in units of the pixels, image distortion and diffused reflection due to a difference in flatness (a portion D) of a final product caused by thick composition of remaining materials ranging from 60 to 200 μm except for a LED chip thickness (approximately 10 μm) are pointed out as problems.

That is, haze or the image distortion may occur when viewing a signage due to a great chip step difference. In this regard, the distortion may be minimized from a front by utilizing the planarizing layer, but the image distortion may appear depending on a viewing angle.

In addition, there is a limitation in reducing the thickness by such a display structure, so that there is difficulty in a flattening process when manufacturing the display.

Accordingly, structural improvements are required to overcome such problems.

### SUMMARY

### Technical Problem

The present disclosure is to provide a display device using a micro LED that may increase color sharpness by reducing a step difference in a substrate thickness in implementing the display device using an LED package as a light source in units of a pixel.

In addition, the present disclosure is to provide a display device using a micro LED that may prevent diffused reflection and thus increase display visibility.

In addition, the present disclosure is to provide a display device using a micro LED that may improve placement efficiency by optimizing a TFT arrangement structure and mount an additional sensor auxiliary device on a TFT substrate.

### Technical Solutions

As a first aspect for achieving the above object, a display device using a light-emitting element may include a TFT substrate including a thin film transistor (TFT) for driving active matrix and a connection pad respectively connected to the TFT, a light emitting package including a unit pixel disposed on the TFT substrate and electrically connected to the connection pad, wherein the light emitting package includes a transparent resin layer, the wiring layer disposed on the TFT substrate, and at least one light-emitting element disposed between the TFT substrate and the transparent resin layer and electrically connected to the wiring layer to constitute a sub-pixel, and a connection wiring for electrically connecting the wiring layer and the connection pad.

In addition, the light emitting package includes the light-emitting elements emitting red, green, and blue light attached on the transparent resin layer and electrically connected to the respective wiring layer.

In addition, a thickness of the transparent resin layer may be smaller than a thickness of the light-emitting element.

In addition, the TFT substrate may further include an insulating layer for covering the thin film transistor, and an adhesive layer may be disposed between the insulating layer and the wiring layer.

In addition, the connection wiring may electrically connect the wiring layer and the connection pad.

In addition, the wiring layer may include a first wiring layer connected to each connection pad and a first electrode of the light-emitting element, and a second wiring layer connected to a second electrode of the light-emitting element.

In addition, the second wiring layer may be connected to a common electrode.

In addition, the common electrode may be a transparent electrode disposed on the transparent resin layer.

In addition, the common electrode may be connected to the second electrode of the light-emitting element through the transparent resin layer.

In addition, the connection pads of the TFT substrate may include four connection pads for a pixel, and the four connection pads may include three connection pads for connecting three sub-pixels, and one connection pad for connecting an additional sensor auxiliary device.

In addition, the connection pad of the TFT substrate may include four connection pads for a pixel, and the four connection pads may include three connection pads for connecting three sub-pixels, and one connection pad for connecting a common electrode.

In addition, the TFTs may be disposed between the four connection pads.

In addition, the TFTs may be disposed between the four connection pads in a cross shape.

In addition, a pixel electrode of the respective sub-pixel may be disposed along both sides of the TFT arranged in the cross shape.

In addition, the reflective film may be disposed below the light-emitting element.

As a second aspect for achieving the object, a display device using a light-emitting element may include a TFT substrate including a thin film transistor (TFT) for driving active matrix and a connection pad respectively connected to the TFT, a light emitting package including a unit pixel disposed on the TFT substrate and electrically connected to the connection pad, wherein the light emitting package includes a transparent resin layer, a wiring layer disposed on the TFT substrate, and at least one light-emitting element disposed between the TFT substrate and the transparent resin layer, electrically connected to the wiring layer to constitute a sub-pixel, and including a first electrode and a second electrode, a connection wiring for electrically connecting the first electrode and the connection pad, and a transparent electrode electrically connected to the second electrode and disposed on the transparent resin layer.

### Advantageous Effects

According to an embodiment of the present disclosure, following effects are obtained.

First, the entire display device including the TFT substrate and the light emitting package may be flattened at the thickness level of about 10 μm.

Furthermore, the thickness of the upper side of the LEDs is greatly reduced, so that the color sharpness when viewed from the outside may be improved.

In addition, the color sharpness may be increased by reducing the step difference in the thickness of the display device.

In addition, the diffused reflection may be prevented by such flattening, and thus the display visibility may be increased.

In one example, the required additional sensor components such as the touch sensor and the illuminance sensor may be installed within the pixel by utilizing the location of the pad on the TFT substrate. Accordingly, the degree of freedom in the component installation may be greatly increased.

Furthermore, according to another embodiment of the present disclosure, there are additional technical effects not mentioned herein. It may be understood by a person skilled in the art via the entire meaning of the specification and drawings.

### BRIEF DESCRIPTION OF THE DRAWINGS

FIG. 1 is a schematic diagram showing an example of a conventional LED package-based display device.

FIG. 2 is a schematic plan view showing a portion of a TFT substrate of a display device according to a first embodiment of the present disclosure.

FIG. 3 is a plan view showing a display device according to a first embodiment of the present disclosure.

FIG. 4 is a cross-sectional view taken along a line A-A′ in FIG. 3.

FIG. 5 is a plan view showing a display device according to a second embodiment of the present disclosure.

FIG. 6 is a cross-sectional view taken along a line B-B′ in FIG. 5.

FIGS. 7 and 8 are cross-sectional views showing a manufacturing process of a display device according to a second embodiment of the present disclosure.

FIGS. 9 and 10 show variants of a display device according to a second embodiment of the present disclosure.

FIG. 11 is a plan view showing a display device according to a third embodiment of the present disclosure.

FIG. 12 is a cross-sectional view taken along a line C-C′ in FIG. 11.

FIG. 13 is a cross-sectional view showing a display device according to a fourth embodiment of the present disclosure.

FIG. 14 is a cross-sectional view showing a display device according to a fifth embodiment of the present disclosure.

FIGS. 15 and 16 are schematic diagrams showing design of a general TFT substrate.

FIG. 17 is a schematic diagram showing design of a TFT substrate according to an embodiment of the present disclosure.

FIG. 18 is a schematic diagram comparing sizes of areas in an arrangement in FIG. 17.

FIG. 19 is a plan view specifically showing design of a TFT substrate according to an embodiment of the present disclosure.

FIG. 20 is a schematic diagram showing design of a TFT substrate according to another embodiment of the present disclosure.

### DETAILED DESCRIPTION

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions.

In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant PDA, a portable multimedia player PMP, a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting element mentioned in this specification is a concept including an LED, a micro LED, and the like, and may be used interchangeably therewith.

[symbol]

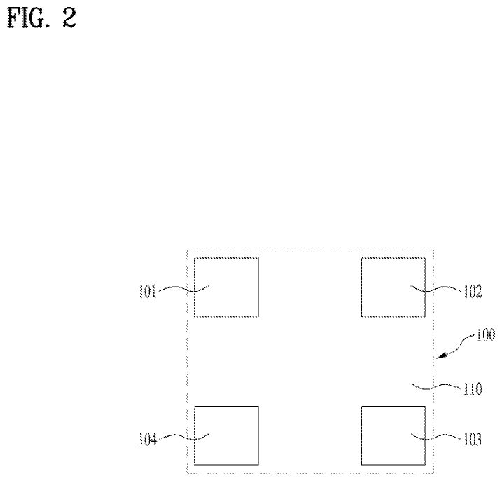

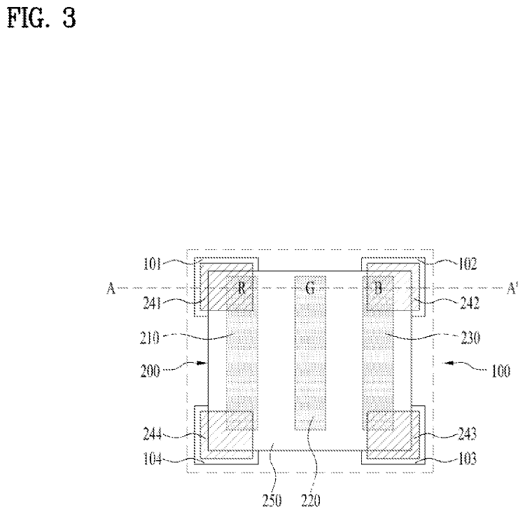

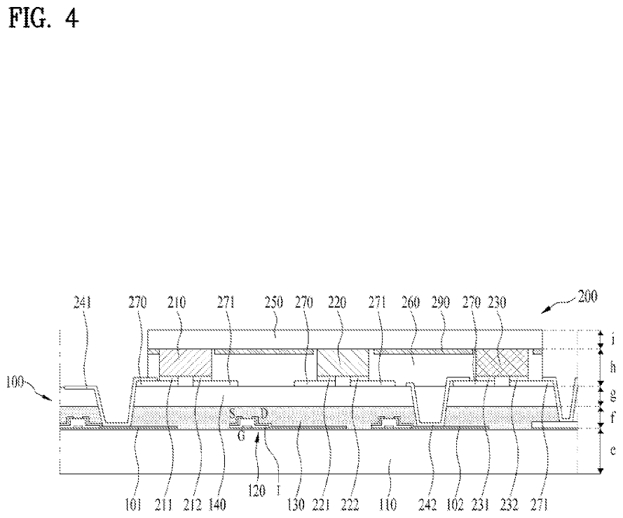

FIG. 2 is a schematic plan view showing a portion of a TFT substrate of a display device according to a first embodiment of the present disclosure. FIG. 3 is a plan view showing a display device according to a first embodiment of the present disclosure. FIG. 4 is a cross-sectional view taken along a line A-A′ in FIG. 3.

Hereinafter, a configuration of the display device according to the first embodiment of the present disclosure will be described with reference to FIGS. 2 to 4. Herein, a description will be made with an example that a pixel of the display device is light emitting diodes (LEDs).

First, referring to FIG. 2, four connection pads 101, 102, 103, and 104 may be arranged on a base substrate 110 in a unit pixel area of the TFT substrate 100. In addition, in the TFT substrate 100, a thin film transistor (TFT) 120 (see FIG. 4) for driving an active matrix may be disposed on the base substrate 110.

Such four connection pads 101, 102, 103, and 104 may be disposed at four corners of the unit pixel area constituting a rectangle, respectively.

Such connection pads may include the first pad 101 to which a first electrode (e.g., a P electrode 211) of a red LED 210 (see FIG. 4) is electrically connected, a second pad 102 to which a first electrode 221 of a green LED 220 is electrically connected, a third pad 103 to which a first electrode 231 of a blue LED 230 is electrically connected, and a fourth pad 104 to which second electrodes (e.g., N electrodes 212, 222, and 232) of the red LED 210, the green LED 220, and the blue LED 230 are connected in common.

Referring to FIG. 3, a light emitting package 200 equipped with such LEDs 210, 220, and 230 and constituting an individual pixel may be mounted on the TFT substrate 100. The red LED 210, the green LED 220, and the blue LED 230 may be mounted in the individual light emitting package 200. Each of such LEDs 210, 220, and 230 may constitute a sub-pixel, and the pixel emitting all natural colors may be formed as the red LED 210, the green LED 220, and the blue LED 230 are turned on.

In the light emitting package 200, the red LED 210, the green LED 220, and the blue LED 230 described above may be attached to and disposed on a transparent resin layer 250.

Such light emitting package 200 may be connected to the TFT substrate 100 via connection wirings 241, 242, 243, and 244. That is, the connection wirings 241, 242, 243, and 244 may be electrically connected to the connection pads 101, 102, 103, and 104 of the TFT substrate 100, respectively. Specifically, the connection wirings 241, 242, 243, and 244 may electrically connect respective pairs of wiring layers 270 and 271 (see FIG. 4) on which the respective LEDs 210, 220, and 230 are mounted and the connection pads 101, 102, 103, and 104 to each other.

Referring to FIG. 4, the thin film transistor (TFT) 120 for driving the active matrix may be disposed on the base substrate 110 of the TFT substrate 100 of the display device according to the first embodiment of the present disclosure.

In such TFT 120, a gate electrode G and an insulating layer I may be disposed on the base substrate 110, a semiconductor layer may be disposed on the insulating layer, and a source electrode S and a drain electrode D may be disposed at both sides of the semiconductor layer. In this regard, further description of the TFT 120 is omitted.

An insulating layer 130 for covering and flattening such TFT 120 may be disposed on the TFT 120, and an adhesive layer 140 may be disposed on such insulating layer 130.

The respective pairs of wiring layers 270 and 271 on which the respective LEDs 210, 220, and 230 are mounted may be arranged on the adhesive layer 140.

Such pairs of wiring layers 270 and 271 may include the first wiring layers 270 respectively connected to the first electrodes 211, 221, and 231 of the LEDs 210, 220, and 230, and the second wiring layers 271 respectively connected to the second electrodes 212, 222, and 232 of the LEDs 210, 220, and 230.

In this regard, the first wiring layer 270 may be a pixel electrode (or a data electrode), and the second wiring layer 271 may be a common electrode. Although not shown in FIGS. 2 to 4, the first wiring layer 270 and the second wiring layer 271 may be arranged to intersect each other. An area where the first wiring layer 270 and the second wiring layer 271 intersect each other as such may form one pixel.

As described above, the first wiring layers 270 may be electrically connected to the connection pads 101, 102, and 103 via the connection wirings 241, 242, and 243, respectively. In addition, the second wiring layers 271 may be electrically connected to the connection pad 104 via the connection wiring 244.

Comparing FIG. 3 with FIG. 4, because FIG. 3 schematically illustrates a plane of the display device, locations of the connection wiring 242 and the second pad 102 may not exactly match each other. However, it will be understood that FIGS. 3 and 4 illustrate a common inventive idea.

In other words, the first electrode 211 of the red LED 210 may be connected to the first wiring layer 270 so as to be connected to the first pad 101 via the connection wiring 241, the first electrode 221 of the green LED 220 may be connected to the first wiring layer 270 so as to be connected to the second pad 102 via the connection wiring 242, and the first electrode 231 of the blue LED 230 may be connected to the first wiring layer 270 so as to be connected to the third pad 103 via the connection wiring 243. In addition, the second electrodes 212, 222, and 232 of the LEDs 210, 220, and 230 may be connected to the second wiring layers 271 so as to be connected to the fourth pad 104 via the connection wiring 244.

In one example, a black matrix 290 may be disposed between adjacent two of the LEDs 210, 220, and 230. Such black matrix 290 may improve contrast of the pixel.

Referring to FIG. 4, it may be seen that each of the LEDs 210, 220, and 230 is disposed between the transparent resin layer 250 and each pair of wiring layers 270 and 271. In this regard, a thickness of the transparent resin layer 250 may be smaller than that of the LEDs 210, 220, and 230.

The LEDs 210, 220, and 230 constituting such sub-pixels may have a size of a micrometer (μm) unit. The micrometer (μm) size may mean that a width of at least one surface of each of the light-emitting elements 210, 220, and 230 has a size of several to hundreds of micrometers (μm). Specifically, in the case of FIG. 4, a thickness in a vertical direction thereof may be about 10 μm. In contrast, a thickness of the transparent resin layer 250 may be about 2 μm.

Referring to FIG. 4, a thickness e of the base substrate 110 is about 500 μm, and a thickness f of the insulating layer 130 including the TFT 120 is about 2 μm. In addition, a thickness g of the adhesive layer 140 may be about 2 μm, and as mentioned above, a thickness h of the LEDs 210, 220, and 230 may be about 10 μm and a thickness i of the transparent resin layer 250 may be about 2 μm.

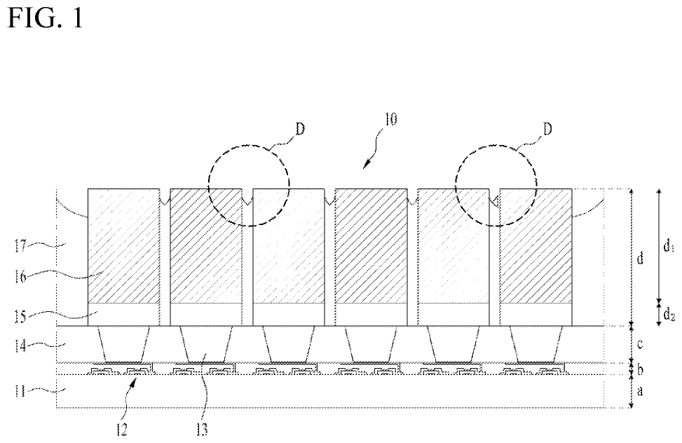

Thus, according to the first embodiment of the present disclosure, it may be seen that a thickness of an upper side of the LEDs, that is, a sum of thicknesses of the LEDs 210, 220, and 230 and the transparent resin layer 250 is about 12 μm. It may be seen that this is a significantly reduced thickness from the thickness in the range from 70 to 200 μm, which is the general case described with reference to FIG. 1.

In particular, because the thickness of the transparent resin layer 250 is about 2 μm, the thickness of the upper side of the LEDs 210, 220, and 230 may be greatly reduced. This indicates that the entire display device including the TFT substrate 100 and the light emitting package 200 may be flattened at a thickness level of about 10 μm considering that a step difference of the sum of the thicknesses of the TFT substrate 100 and the light emitting package 200 is usually about 6 μm.

Furthermore, as described above, the thickness of the upper side of the LEDs 210, 220, and 230 is greatly reduced, so that color sharpness when viewed from the outside may be improved.

In addition, the color sharpness may be increased by reducing the step difference in the thickness of the display device. In addition, diffused reflection may be prevented by such flattening, and thus display visibility may be increased.

[symbol]

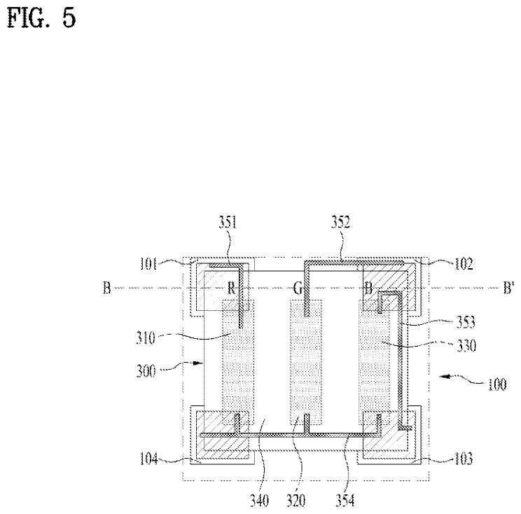

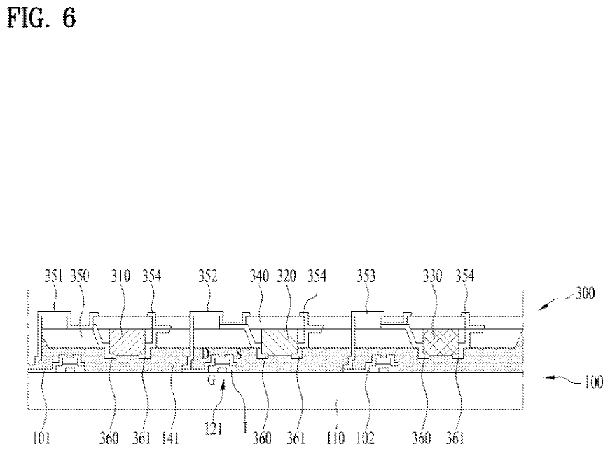

FIG. 5 is a plan view showing a display device according to a second embodiment of the present disclosure. FIG. 6 is a cross-sectional view taken along a line B-B′ in FIG. 5.

Hereinafter, a configuration of the display device according to the second embodiment of the present disclosure will be described with reference to FIGS. 5 and 6. As in the first embodiment, herein, a description will be made with the example that the pixel of the display device is the light emitting diodes (the LEDs).

First, referring to FIGS. 5 and 6, the four connection pads 101, 102, 103, and 104 may be arranged on the base substrate 110 in the unit pixel area of the TFT substrate 100. In addition, in the TFT substrate 100, a thin film transistor (TFT) 121 for driving the active matrix may be disposed on the base substrate 110.

Such four connection pads 101, 102, 103, and 104 may be disposed at the four corners of the unit pixel area constituting the rectangle, respectively.

In this regard, the electrodes of the LED are not specifically shown. However, it may be understood that there are the first electrode and the second electrode as in the first embodiment. Hereinafter, the first electrode and the second electrode of the LED will be briefly described as one side and the other side, respectively.

Such connection pads 101, 102, 103, and 104 may include the first pad 101 electrically connected to one side of a red LED 310, the second pad 102 electrically connected to one side of a green LED 320, the third pad 103 electrically connected to one side of a blue LED 330, and the fourth pad 104 connected to the other sides of the red LED 310, the green LED 320, and the blue LED 330 in common.

A light emitting package 300 equipped with such LEDs 310, 320, and 330 and constituting an individual pixel may be mounted on the TFT substrate 100. The red LED 310, the green LED 320, and the blue LED 330 may be mounted in the individual light emitting package 300. Each of such LEDs 310, 320, and 330 may constitute a sub-pixel, and the pixel emitting all natural colors may be formed as the red LED 310, the green LED 320, and the blue LED 330 are turned on.

In the light emitting package 200, the red LED 310, the green LED 320, and the blue LED 330 described above may be attached to and disposed on a transparent resin layer 340.

Such light emitting package 300 may be connected to the TFT substrate 100 via connection wirings 351, 352, 353, and 354. That is, the connection wirings 351, 352, 353, and 354 may be electrically connected to the connection pads 101, 102, 103, and 104 of the TFT substrate 100, respectively. Specifically, the connection wirings 351, 352, 353, and 354 may electrically connect respective pairs of wiring layers 360 and 361 on which the respective LEDs 310, 320, and 330 are mounted and the connection pads 101, 102, 103, and 104 to each other.

Referring to FIG. 6, the thin film transistor (TFT) 121 for driving the active matrix may be disposed on the base substrate 110 of the TFT substrate 100 of the display device according to the second embodiment of the present disclosure. In this regard, further description of the TFT 121 is omitted.

An adhesive layer 141 for covering such TFT 121 and for attaching the light emitting package 300 may be disposed on the TFT 121. The respective pairs of wiring layers 360 and 361 on which the respective LEDs 310, 320, and 330 are mounted may be arranged on the adhesive layer 141.

Such pair of wiring layers 360 and 361 may include the first wiring layer 360 connected to one side of each of the LEDs 310, 320, and 330, and the second wiring layer 361 connected to the other side of each of the LEDs 310, 320, and 330.

In this regard, as described above, the first wiring layer 360 may be the pixel electrode (or the data electrode), and the second wiring layer 361 may be the common electrode. Although not shown in FIGS. 5 and 6, the first wiring layer 360 and the second wiring layer 361 may be arranged to intersect each other. An area where the first wiring layer 360 and the second wiring layer 361 intersect each other as such may form one pixel.

As described above, the first wiring layers 360 may be electrically connected to the connection pads 101, 102, and 103 via the connection wirings 351, 352, and 353, respectively. In addition, the second wiring layers 361 may be electrically connected to the connection pad 104 via the connection wiring 354.

Comparing FIG. 5 with FIG. 6, because FIG. 5 schematically illustrates a plane of the display device, locations of the components may not exactly match each other.

Referring to FIG. 4, it may be seen that each of the LEDs 310, 320, and 330 is connected to the transparent resin layer 340 through the insulating layer 350 by each pair of wiring layers 360 and 361. In this regard, the connection wirings 351, 352, 353, and 354 may be connected to the pairs of wiring layers 360 and 361 through the transparent resin layer 340.

In this regard, it may be seen that one sides of the respective LEDs 310, 320, and 330 and one sides (lower sides in FIG. 6) of the wiring layers 360 and 361 penetrate into the adhesive layer 141 and are disposed in the adhesive layer 141. That is, when the lower sides of the respective LEDs 310, 320, and 330 and the wiring layers 360 and 361 are attached to the TFT substrate 100 by the adhesive layer 141, the lower sides thereof may be disposed inside the adhesive layer 141.

In this regard, a thickness of the transparent resin layer 340 may be smaller than that of the LEDs 310, 320, and 330.

The LEDs 310, 320, and 330 constituting such sub-pixels may have a size of a micrometer (μm) unit. The micrometer (μm) size may mean that a width of at least one surface of each of the light-emitting elements 310, 320, and 330 has a size of several to hundreds of micrometers (μm).

As such, according to the second embodiment of the present disclosure, it may be seen that a thickness of an upper side of the LEDs, that is, a sum of thicknesses of the LEDs 310, 320, and 330 and the transparent resin layer 340 is about 12 μm. Moreover, in the present embodiment, because one sides of the LEDs 310, 320, and 330 penetrate into and are disposed in the adhesive layer 141, an overall thickness may be further reduced. In addition, in a process of attaching the LEDs 310, 320, and 330 by the adhesive layer 141, thickness variation may be absorbed.

In particular, because the thickness of the transparent resin layer 340 is about 2 μm, the thickness of the upper side of the LEDs 310, 320, and 330 may be greatly reduced. This indicates that the entire display device including the TFT substrate 100 and the light emitting package 300 may be flattened at the thickness level of about 10 μm considering that a step difference of the sum of the thicknesses of the TFT substrate 100 and the light emitting package 300 is usually about 6 μm.

Furthermore, as such, the thickness of the upper side of the LEDs 310, 320, and 330 is greatly reduced, so that the color sharpness when viewed from the outside may be improved.

In addition, the color sharpness may be increased by reducing the step difference in the thickness of the display device. In addition, the diffused reflection may be prevented by such flattening, and thus the display visibility may be increased.

[symbol]

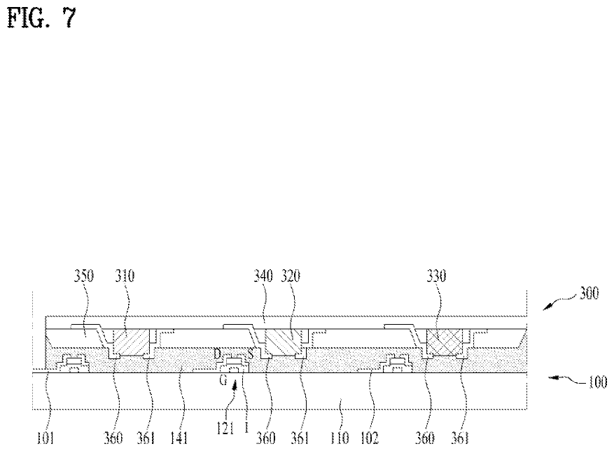

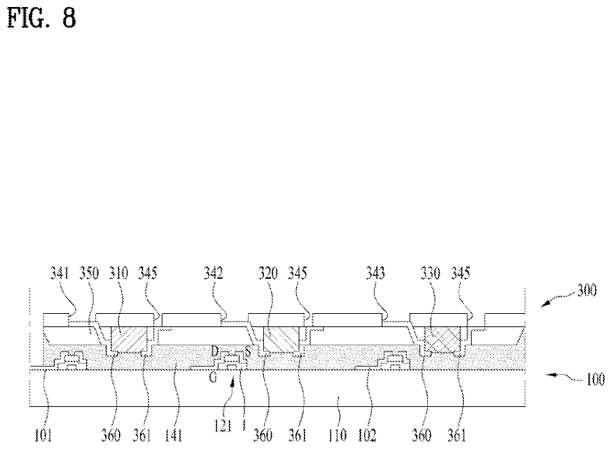

FIGS. 7 and 8 are cross-sectional views showing a manufacturing process of a display device according to a second embodiment of the present disclosure. Hereinafter, the manufacturing process of the display device according to the second embodiment of the present disclosure will be briefly described with reference to FIGS. 7 and 8.

First, when the TFT substrate 100 and the light emitting package 300 are adhered to each other using the adhesive layer 141, a state shown in FIG. 7 may be obtained. In this regard, as described above, because one sides of the LEDs 310, 320, and 330 penetrate into and are disposed in the adhesive layer 141, the overall thickness may be further reduced. In addition, in the process of attaching the LEDs 310, 320, and 330 by the adhesive layer 141, the thickness variation may be absorbed.

Subsequently, as shown in FIG. 8, through-holes 341, 342, 343, and 345 may be defined for connection of the connection wirings 351, 352, 353, and 354.

That is, the first through-hole 341 for connection of one side of the red LED 310, the second through-hole 342 for connection of one side of the green LED 320, the third through-hole 343 connection of one side of the blue LED 330, and the fourth through-hole 345 for connection of the other sides of the red LED 310, the green LED 320, and the blue LED 330 may be defined.

Thereafter, the connection wirings 351, 352, 353, and 354 may be electrically connected to the connection pads 101, 102, 103, and 104 of the TFT substrate 100 via the through-holes 341, 342, 343, and 345, respectively. Specifically, the connection wirings 351, 352, 353, and 354 may electrically connect the respective pairs of wiring layers 360 and 361 on which the respective LEDs 310, 320, and 330 are mounted and the connection pads 101, 102, 103, and 104 to each other.

As such, when the connection wirings 351, 352, 353, and 354 are installed via the through-holes 341, 342, 343, and 345, the state shown in FIG. 6 may be obtained.

[symbol]

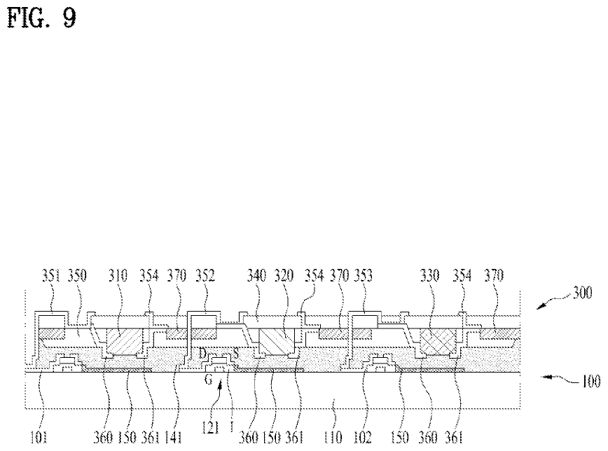

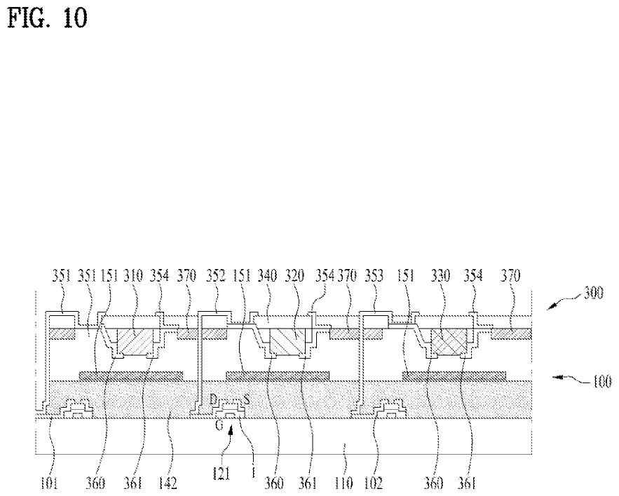

FIGS. 9 and 10 show variants of a display device according to a second embodiment of the present disclosure. That is, FIGS. 9 and 10 show the variants for improving reflectivity in the display device according to the second embodiment of the present disclosure.

First, referring to FIG. 9, the same configuration as that in FIG. 6 is shown, but each reflective film 150 may be disposed on one side (e.g., a side of a source S) of each TFT 121. In addition, the wiring layers 360 and 361 may be made of an electrode metal having high reflectivity.

In this case, the reflective film 150 may increase a light emission efficiency by reflecting light emitted from each of the LEDs 310, 320, and 330 upward. In addition, the reflective film 150 may prevent deterioration of TFT characteristics by preventing the light emitted from each of the LEDs 310, 320, and 330 from being incident on each TFT 121 as it is.

Therefore, in this case, the reflective film 150 may be disposed directly below each of the LEDs 310, 320, and 330 and on one side of each TFT 121.

In one example, a black matrix 370 may be disposed between adjacent two of the LEDs 310, 320, and 330. Such black matrix 370 may improve the contrast of the pixel.

In one example, referring to FIG. 10, an embodiment in which a reflective film 151 is disposed on an adhesive layer 142 is illustrated. In this case, the adhesive layer 142 may be an insulating layer.

In this regard, each reflective film 151 may be interposed between each TFT 121 and each of the LEDs 310, 320, and 330. That is, the reflective film 151 may increase the light emitting efficiency by reflecting light emitted from each of the LEDs 310, 320, and 330 upward. At the same time, the reflective film 151 may prevent the deterioration of the TFT characteristics by preventing the light emitted from each of the LEDs 310, 320, and 330 from being incident on each TFT 121 as it is.

[symbol]

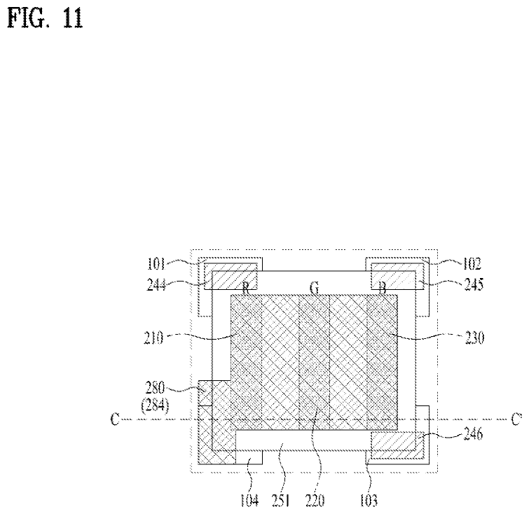

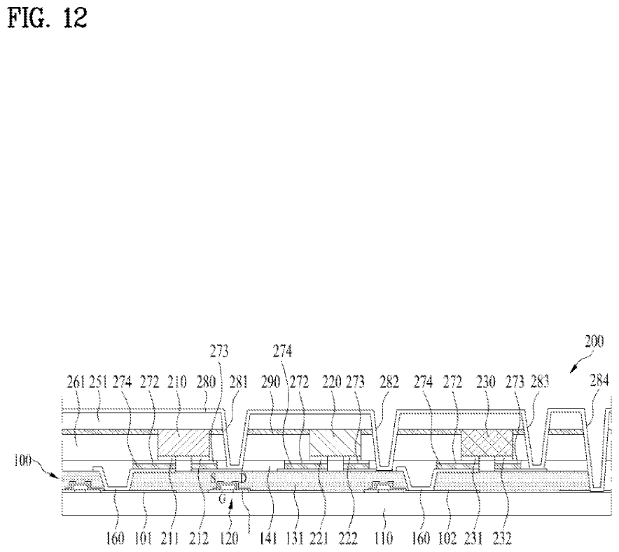

FIG. 11 is a plan view showing a display device according to a third embodiment of the present disclosure. FIG. 12 is a cross-sectional view taken along a line C-C′ in FIG. 11.

Hereinafter, a configuration of the display device according to the third embodiment of the present disclosure will be described with reference to FIGS. 11 and 12. Herein, a description will be made with the example that the pixel of the display device is the light emitting diodes (the LEDs).

First, referring to FIG. 11, the four connection pads 101, 102, 103, and 104 may be arranged on the base substrate 110 in the unit pixel area of the TFT substrate 100. In addition, in the TFT substrate 100, the thin film transistor (TFT) 120 for driving the active matrix may be disposed on the base substrate 110.

Such four connection pads 101, 102, 103, and 104 may be disposed at the four corners of the unit pixel area constituting the rectangle, respectively.

Such connection pads may include the first pad 101 to which the first electrode (e.g., the P electrode 211) of the red LED 210 is electrically connected, the second pad 102 to which the first electrode 221 of the green LED 220 is electrically connected, the third pad 103 to which the first electrode 231 of the blue LED 230 is electrically connected, and the fourth pad 104 to which the second electrodes (e.g., the N electrodes 212, 222, and 232) of the red LED 210, the green LED 220, and the blue LED 230 are connected in common.

Referring to FIG. 12, the light emitting package 200 equipped with such LEDs 210, 220, and 230 and constituting the individual pixel may be mounted on the TFT substrate 100. The red LED 210, the green LED 220, and the blue LED 230 may be mounted in the individual light emitting package 200. Each of such LEDs 210, 220, and 230 may constitute the sub-pixel, and the pixel emitting all natural colors may be formed as the red LED 210, the green LED 220, and the blue LED 230 are turned on.

In the light emitting package 200, the red LED 210, the green LED 220, and the blue LED 230 described above may be attached to and disposed on a transparent resin layer 251.

Such light emitting package 200 may be connected to the TFT substrate 100 via connection wirings. That is, connection wirings 150 may be electrically connected to the connection pads 101, 102, and 103 of the TFT substrate 100, respectively. Specifically, the connection wirings 150 may electrically connect respective first wiring layers 272 on which the respective LEDs 210, 220, and 230 are mounted and the connection pads 101, 102, and 103 to each other.

In one example, each second wiring layer 273 may be electrically connected to each of the second electrodes 212, 222, and 232 of each of the LEDs 210, 220, and 230 by a transparent electrode 280 and each of curved connection portions 281, 282, and 283 of such transparent electrode 280.

Referring to FIG. 12, the thin film transistor (TFT) 120 for driving the active matrix may be disposed on the base substrate 110 of the TFT substrate 100 of the display device according to the third embodiment of the present disclosure. In this regard, further description of the TFT 120 is omitted.

An insulating layer 131 for covering such TFT 120 may be disposed on the TFT 120. The respective pairs of wiring layers 272 and 273 on which the respective LEDs 210, 220, and 230 are mounted may be arranged on the insulating layer 131.

Such pairs of wiring layers 272 and 273 may include the first wiring layers 272 respectively connected to the first electrodes 211, 221, and 231 of the LEDs 210, 220, and 230, and the second wiring layers 273 respectively connected to the second electrodes 212, 222, and 232 of the LEDs 210, 220, and 230.

In this regard, as described above, the first wiring layer 272 may be the pixel electrode (or the data electrode), and the second wiring layer 273 may be the common electrode. Although not shown in FIGS. 11 and 12, the first wiring layer 272 and the second wiring layer 273 may be arranged to intersect each other. An area where the first wiring layer 272 and the second wiring layer 273 intersect each other as such may form one pixel.

In one example, each pair of the first wiring layer 272 and the second wiring layer 273 may be connected to each connection wiring 150 by solder or a coupling metal 274. In addition, such connection wiring 150 may be connected to the drain (D) electrode of the TFT 120.

Referring to FIG. 12, as mentioned above, the transparent electrode 280 may be disposed on the transparent resin layer 251. The connection portions 281, 282, and 283 respectively connected to the connection wirings 150 through the light emitting package 200 may be integrally connected to the transparent electrode 280.

In this regard, each connection wiring 150 may be electrically connected to each second wiring layer 273 and each of the second electrodes 212, 222, and 232 of the respective LEDs 210, 220, and 230 by the solder or the coupling metal 274. Accordingly, the transparent electrode 280 may form the common electrode and be electrically connected to the second electrodes 212, 222, and 232 of the LEDs 210, 220, and 230.

In this regard, as described above, the thickness of the transparent resin layer 340 may be smaller than that of the LEDs 210, 220, and 230. The LEDs 210, 220, and 230 constituting such sub-pixels may have the size of the micrometer (μm) unit.

As such, according to the third embodiment of the present disclosure, it may be seen that a thickness of an upper side of the LEDs, that is, the sum of the thicknesses of the LEDs 210, 220, and 230 and the transparent resin layer 251 is about 12 μm.

In particular, because the thickness of the transparent resin layer 251 is about 2 μm, the thickness of the upper side of the LEDs 210, 220, and 230 may be greatly reduced. This indicates that the entire display device including the TFT substrate 100 and the light emitting package 200 may be flattened at the thickness level of about 10 μm considering that the step difference of the sum of the thicknesses of the TFT substrate 100 and the light emitting package 200 is usually about 6 μm.

Furthermore, as such, the thickness of the upper side of the LEDs 210, 220, and 230 is greatly reduced, so that the color sharpness when viewed from the outside may be improved.

In addition, the color sharpness may be increased by reducing the step difference in the thickness of the display device. In addition, the diffused reflection may be prevented by such flattening, and thus the display visibility may be increased.

In one example, because the transparent electrode 280 may be used as the common electrode in the present third embodiment, in the TFT substrate 100, the fourth pad 104 to which the second electrodes (e.g., the N electrodes; 212, 222, and 232) of the red LED 210, the green LED 220, and the blue LED 230 are connected in common may not be needed.

Accordingly, sensor components such as additional touch sensor and illuminance sensor required within the pixel may be installed at a location of such fourth pad 104. A space in a design of the TFT substrate 100 is very narrow. Such problem may become more severe with higher resolutions. Accordingly, when the pad is removed as such, a degree of freedom in component installation may be greatly increased.

[symbol]

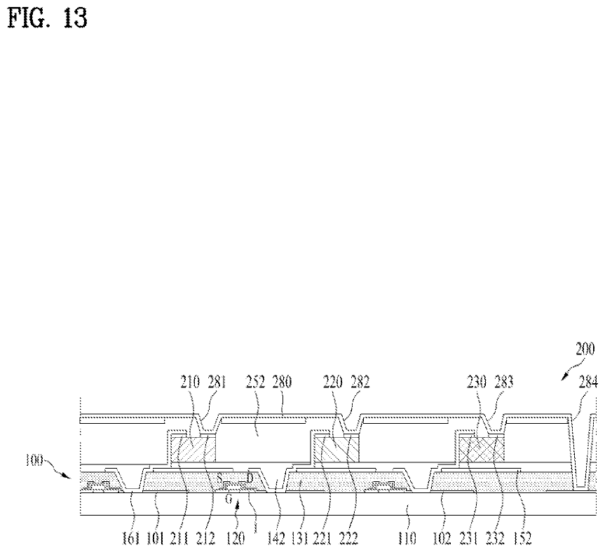

FIG. 13 is a cross-sectional view showing a display device according to a fourth embodiment of the present disclosure. Referring to FIG. 13, it may be seen that the fourth embodiment is similar to the third embodiment, but has a more simplified structure of connection with the transparent electrode 280 by reversing the positions of the LEDs.

Hereinafter, the display device according to the fourth embodiment of the present disclosure will be described with reference to FIG. 13 mainly focusing on differences from the third embodiment.

Referring to FIG. 13, the light emitting package 200 equipped with such LEDs 210, 220, and 230 and constituting the individual pixel may be mounted on the TFT substrate 100. The red LED 210, the green LED 220, and the blue LED 230 may be mounted in the individual light emitting package 200.

In the light emitting package 200, the red LED 210, the green LED 220, and the blue LED 230 may be disposed inside a transparent resin layer 252 by being attached thereto from above. In this regard, the red LED 210, the green LED 220, and the blue LED 230 may be installed by being flip-chip bonded upwards.

Such light emitting package 200 may be connected to the TFT substrate 100 via connection wirings 161. That is, the connection wiring 161 may be electrically connected to each of the connection pads 101, 102, and 103 of the TFT substrate 100.

The insulating layer 131 for covering such TFT 120 may be disposed on the TFT 120. On such insulating layer 131, the reflective films 152 may be disposed below the positions where the LEDs 210, 220, and 230 are mounted.

As such, the first electrodes 211, 221, and 231 of the respective LEDs 210, 220, and 230 may be electrically connected to the connection pads 101, 102, and 103 via the connection wirings 161, respectively.

In addition, the transparent electrode 280 may be disposed on the transparent resin layer 251. The connection portions 281, 282, and 283 respectively connected to the connection wirings 150 through the light emitting package 200 may be integrally connected to the transparent electrode 280.

Accordingly, the transparent electrode 280 may form the common electrode and be electrically connected to the second electrodes 212, 222, and 232 of the LEDs 210, 220, and 230.

In one example, the black matrix may be disposed between adjacent two of the LEDs 210, 220, and 230 and immediately beneath the transparent electrode 280.

Hereinafter, description duplicated with that of the third embodiment will be omitted.

[symbol]

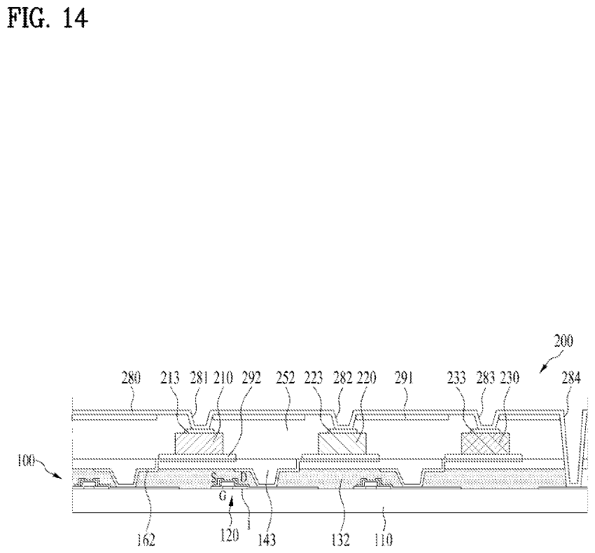

FIG. 14 is a cross-sectional view showing a display device according to a fifth embodiment of the present disclosure. Referring to FIG. 14, it is similar to the fourth embodiment, but there is a difference in that a vertical type LED is used.

Hereinafter, the display device according to the fifth embodiment of the present disclosure will be described with reference to FIG. 14 mainly focusing on differences from the third embodiment and the fourth embodiment.

Referring to FIG. 14, the light emitting package 200 equipped with such LEDs 210, 220, and 230 and constituting the individual pixel may be mounted on the TFT substrate 100. The red LED 210, the green LED 220, and the blue LED 230 may be mounted in the individual light emitting package 200.

In the light emitting package 200, the red LED 210, the green LED 220, and the blue LED 230 of the vertical type may be disposed inside the transparent resin layer 252 by being attached thereto from above. In this regard, the first electrodes (lower electrodes; not shown) of the red LED 210, the green LED 220, and the blue LED 230 of the vertical type may be connected to respective wiring layers 292 and the second electrodes (upper electrodes) 213, 223, and 233 thereof may be connected to the transparent electrode 280.

Such light emitting package 200 may be connected to the TFT substrate 100 via connection wirings 162. That is, each connection wiring 162 may be electrically connected to each of the connection pads 101, 102, and 103 of the TFT substrate 100. In addition, each connection wiring 162 may be connected to each wiring layer 292.

An insulating layer 132 for covering the TFT 120 may be disposed on the TFT 120.

In addition, the transparent electrode 280 may be disposed on the transparent resin layer 252. The connection portions 281, 282, and 283 respectively connected to the second electrodes (the upper electrodes) 213, 223, and 233 of the LEDs through the light emitting package 200 may be integrally connected to the transparent electrode 280.

Accordingly, the transparent electrode 280 may form the common electrode and be electrically connected to the second electrodes 213, 223, and 233 of the LEDs 210, 220, and 230.

In one example, a black matrix 291 may be disposed between adjacent two of the LEDs 210, 220, and 230 and immediately beneath the transparent electrode 280.

Hereinafter, descriptions duplicated with those of the third and fourth embodiments will be omitted.

[symbol]

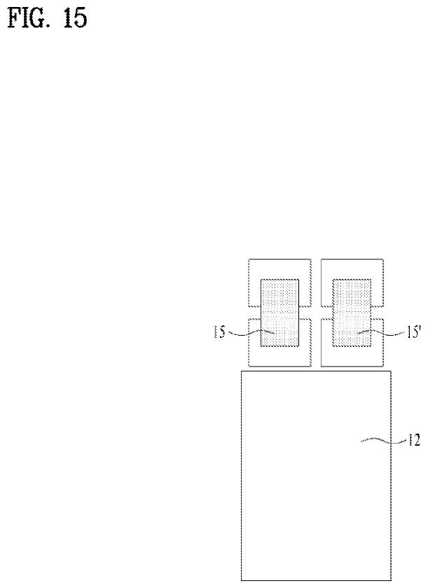

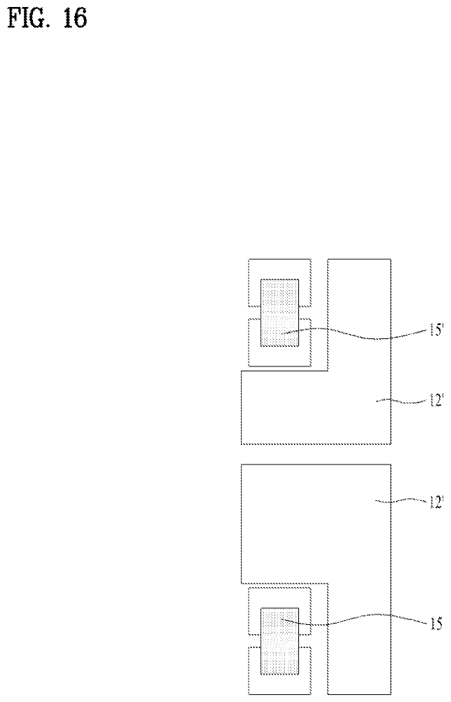

FIGS. 15 and 16 are schematic diagrams showing design of a general TFT substrate.

Referring to FIGS. 15 and 16, pixel design is generally divided into TFT portions 12 and 12′ and LED portions (light emitting areas) 15 and 15′.

In this regard, the extra LED 15′ and the extra TFT portion (a TFT circuit) 12′ may be arranged to prepare for a failure of the LED.

As such, when the design is made by separating the light emitting area and the TFT area from each other, space may be greatly restricted. In addition, such limitation may become severe as the resolution increases.

[symbol]

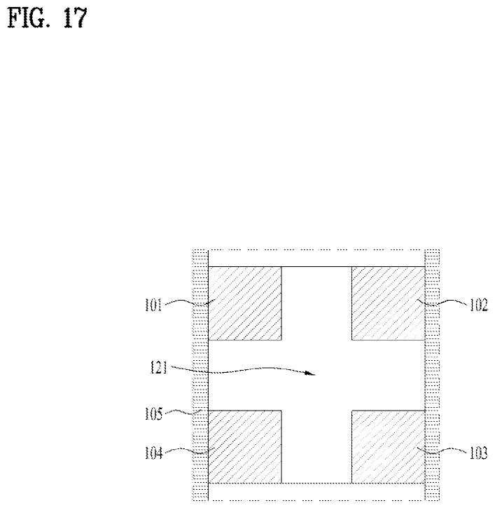

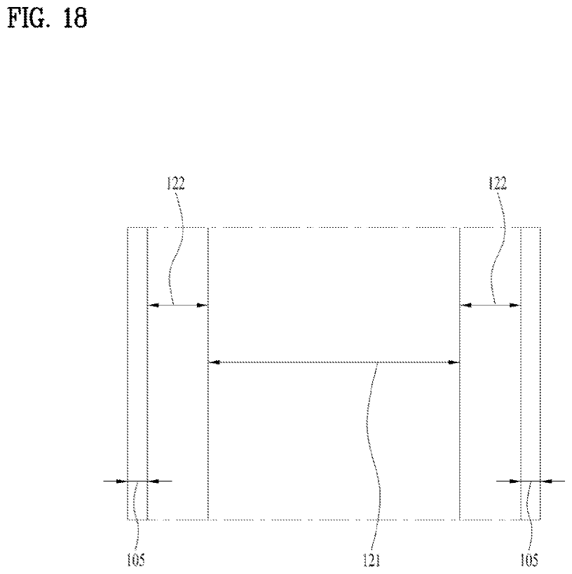

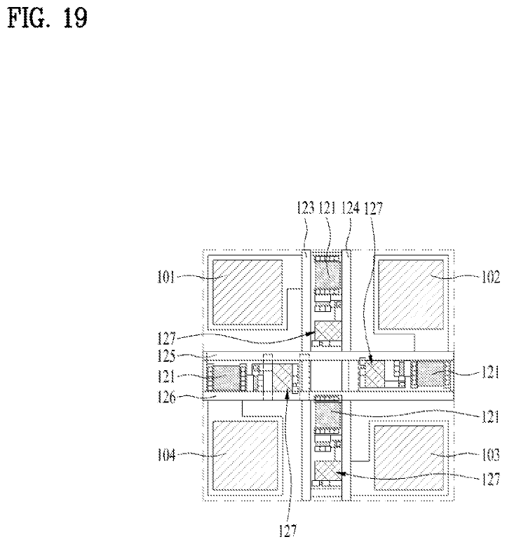

FIG. 17 is a schematic diagram showing design of a TFT substrate according to an embodiment of the present disclosure. FIG. 18 is a schematic diagram comparing sizes of areas in an arrangement in FIG. 17. FIG. 19 is a plan view specifically showing design of a TFT substrate according to an embodiment of the present disclosure.

FIG. 17 shows an example of the TFT substrate 100 described in the first to fifth embodiments above. Therefore, a content described herein may be applied as it is to the first to fifth embodiments described above.

Referring to FIG. 17, a TFT circuit 121 may be formed in an inner area 121 of the pads 101, 102, 103, and 104.

That is, as described above, the connection pads of the TFT substrate 100 include the four connection pads 101, 102, 103, and 104 for each pixel, and the four connection pads 101, 102, 103, and 104 may include the connection pads 101, 102, and 103 for the connection of the three sub-pixels and one connection pad 104 for the connection of the common electrode.

In this regard, the TFTs 121 may be disposed in a space between such connection pads 101, 102, 103, and 104.

In this regard, left and right edges may correspond to bezel areas 105.

When designing the TFT 121 as such, referring to FIG. 18, a space for the TFT 121 may be efficiently used. Signal wiring areas 122 may be symmetrically disposed outwardly of the TFT 121 area, and the bezel areas 105 may be symmetrically disposed outwardly of the respective signal wiring areas 122.

Referring to FIG. 19, the TFTs 121 may be disposed between such four connection pads 101, 102, 103, and 104 and arranged in a cross shape.

In addition, pixel electrodes 123, 124, and 125 of the respective sub-pixels may be disposed along both sides of the cross-shaped TFT area 121. A common electrode 126 may be disposed in parallel with one of the pixel electrodes 123, 124, and 125.

Each of the TFTs 121 arranged in the cross shape as such may include at least one TFT area 121, a capacitor 127, and the like. Herein, a detailed description of a configuration of the TFT 121 will be omitted.

As the display device has the higher resolution, the area where the TFT is to be placed may not be free. However, as TFTs 121 are arranged between the four connection pads 101, 102, 103, and 104 in the cross shape as described above, a degree of freedom in the design may be increased and the space may be efficiently used.

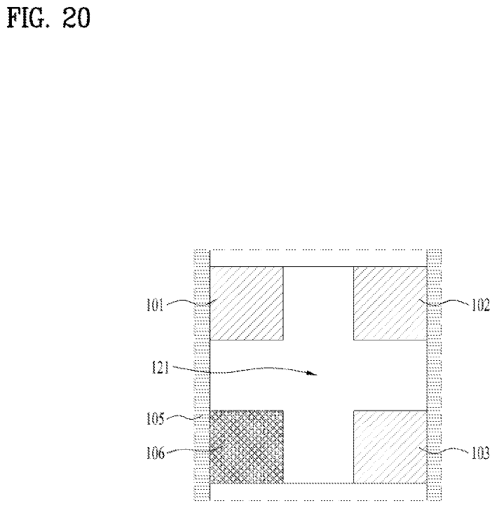

FIG. 20 is a schematic diagram showing design of a TFT substrate according to another embodiment of the present disclosure. In particular, the present embodiment may be applied to the third to fourth embodiments in which the transparent electrode is commonly used at the top. In some cases, the present embodiment may also be applied to the second embodiment using the electrode at the top.

As described above, because the transparent electrode 280 may be used as the common electrode in the third to fifth embodiments, the fourth pad 104 to which the second electrodes (e.g., the N electrodes) 212, 222, and 232 of the red LED 210, the green LED 220, and the blue LED 230 are commonly connected may not be needed in the TFT substrate 100.

Accordingly, the sensor components such as the additional touch sensor and illuminance sensor required within the pixel may be installed at the location of such fourth pad 104. The space in the design of the TFT substrate 100 is very narrow. Such problem may become more severe with the higher resolutions. Accordingly, when the pad is removed as such, the degree of freedom in the component installation may be greatly increased.

There is not enough space to install the required additional sensor in the TFT design. However, as shown, because an area occupied by one pad 104 is large, the degree of freedom in the design may be increased and the space may be used efficiently as the pad 104 is removed.

[symbol]

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL APPLICABILITY

According to the present disclosure, the display device using the micro light emitting diode (LED) may be provided.

1. A display device using a light-emitting element, the display device comprising:
a TFT substrate including:
a thin film transistor (TFT) for driving an active matrix, and
a connection pad connected to the TFT;
a light emitting package including a unit pixel disposed on the TFT substrate and electrically connected to the connection pad,
wherein the light emitting package includes a transparent resin layer, a wiring layer disposed on the TFT substrate, and at least one light-emitting element disposed between the TFT substrate and the transparent resin layer,
wherein the at least one light-emitting element is electrically connected to the wiring layer to constitute a sub-pixel; and
a connection wiring electrically connecting the wiring layer and the connection pad.

2. The display device of claim 1, wherein the light emitting package includes the light-emitting elements emitting red, green, and blue light attached to the transparent resin layer and electrically connected to the respective wiring layer.

3. The display device of claim 1, wherein a thickness of the transparent resin layer is smaller than a thickness of the light-emitting element.

4. The display device of claim 1,
wherein the TFT substrate further includes an insulating layer for covering the TFT, and
wherein an adhesive layer is disposed between the insulating layer and the wiring layer.

5. The display device of claim 1, wherein the connection wiring electrically connects the wiring layer and the connection pad.

6. The display device of claim 1, wherein the wiring layer includes:
a first wiring layer connected to the connection pad and a first electrode of the light-emitting element; and
a second wiring layer connected to a second electrode of the light-emitting element.

7. The display device of claim 6, wherein the second wiring layer is connected to a common electrode.

8. The display device of claim 7, wherein the common electrode is a transparent electrode disposed on the transparent resin layer.

9. The display device of claim 8, wherein the common electrode is connected to the second electrode of the light-emitting element through the transparent resin layer.

10. The display device of claim 8, wherein the connection pad of the TFT substrate include four connection pads for each pixel, wherein the four connection pads include:
three connection pads for connecting three sub-pixels; and
one connection pad for connecting an additional sensor auxiliary device.

11. The display device of claim 1,
wherein the connection pads of the TFT substrate include four connection pads for each pixel,
wherein the four connection pads include:
three connection pads for connecting three sub-pixels; and
one connection pad for connecting a common electrode.

12. The display device of claim 10, wherein the TFT is disposed between the four connection pads.

13. The display device of claim 12, wherein the TFTs are disposed between the four connection pads in a cross shape.

14. The display device of claim 13, wherein pixel electrodes of the respective sub-pixels are disposed along both sides of the TFTs arranged in the cross shape.

15. The display device of claim 1, wherein the reflective film is disposed below the light-emitting element.

16. A display device using a light-emitting element, the display device comprising:
a TFT substrate including a thin film transistor (TFT) for driving an active matrix and a connection pad connected to the TFT;
a light emitting package including a unit pixel disposed on the TFT substrate and electrically connected to the connection pad, wherein the light emitting package includes a transparent resin layer, a wiring layer positioned on the TFT substrate, and at least one light-emitting element disposed between the TFT substrate and the transparent resin layer, wherein the at least one light-emitting element is electrically connected to the wiring layer to constitute a sub-pixel, and includes a first electrode and a second electrode;
a connection wiring electrically connecting the first electrode and each connection pad; and
a transparent electrode electrically connected to the second electrode and positioned on the transparent resin layer.

17. The display device of claim 16, wherein the common electrode is connected to the second electrode of the light-emitting element through the transparent resin layer.

18. The display device of claim 16, wherein a thickness of the transparent resin layer is smaller than a thickness of the light-emitting element.

19. The display device of claim 16, wherein the connection pads of the TFT substrate include four connection pads for each pixel, wherein the four connection pads include:
three connection pads for connecting three sub-pixels; and
one connection pad for connecting an additional sensor auxiliary device.

20. The display device of claim 19, wherein the TFT is arranged between the four connection pads in a cross shape.
